(19) United States
(12) Patent Application Publication
(10) Pub. No.: US 2019/0204171 A1
(43) Pub. Date: Jul. 4, 2019

(54) PRESSURE SENSOR

(71) Applicant: DENSO CORPORATION, Kariya-city (JP)

(72) Inventors: Akira INABA, Kariya-city (JP); Minoru MURATA, Kariya-city (JP)

(21) Appl. No.: 16/296,920

(22) Filed: Mar. 8, 2019

Related U.S. Application Data
(63) Continuation of application No. PCT/JP2017/032337, filed on Sep. 7, 2017.

(30) Foreign Application Priority Data
Oct. 18, 2016 (JP) 2016-204478

(51) Int. Cl. G01L 9/00; B81B 7/00

(52) U.S. Cl. CPC G01L 9/0051; B81B 2203/0127; B81B 2201/0264; B81B 7/0048

(57) ABSTRACT

A pressure sensor may include a sensor chip and a support member. The sensor chip may include a diaphragm and an inner space. The diaphragm may have a thin plate shape. The diaphragm may be bent in a thickness direction by a fluid pressure. The inner space may be provided by a space adjacent to the diaphragm in the thickness direction. The support member may support the sensor chip at a position separated from the diaphragm. An outer shape of the sensor chip may be provided by a polygonal shape or a circular shape. An outer shape of the diaphragm may be provided by a polygonal shape or a circular shape.

### CROSS REFERENCE TO RELATED APPLICATIONS

The present application is a continuation application of International Patent Application No. PCT/JP2017/032337 filed on Sep. 7, 2017, which designated the U.S. and claims the benefit of priority from Japanese Patent Application No. 2016-204478 filed on Oct. 18, 2016. The entire disclosures of all of the above applications are incorporated herein by reference.

### TECHNICAL FIELD

The present disclosure relates to a pressure sensor.

### BACKGROUND

A pressure sensor having a structure, in which a sensor chip forming a diaphragm is joined to a base and the base is attached to a pedestal provided by a package via an adhesive, is known.

### SUMMARY

A pressure sensor may include a sensor chip and a support member. The sensor chip may include a diaphragm and an inner space. The support member may support the sensor chip at a position separated from the diaphragm. An outer shape of the sensor chip may be provided by a polygonal shape or a circular shape. An outer shape of the diaphragm may be provided by a polygonal shape or a circular shape.

### BRIEF DESCRIPTION OF DRAWINGS

The above and other objects, features and advantages of the present invention will become more apparent from the following detailed description made with reference to the accompanying drawings. In the drawings:

FIG. 1 is a side cross-sectional view showing a schematic configuration of a pressure sensor according to a first embodiment;

FIG. 2 is a plan view showing a sensor chip shown in FIG. 1;

FIG. 3 is a graph showing simulation results of the pressure sensor of the first embodiment;

FIG. 4 is a graph showing simulation results of a pressure sensor of a second embodiment;

FIG. 5 is a plan view showing a schematic configuration of a pressure sensor according to a modification;

FIG. 6 is a plan view showing a schematic configuration of a pressure sensor according to another modification;

FIG. 7 is a side cross-sectional view showing a schematic configuration of a pressure sensor according to another modification;

FIG. 8 is a side cross-sectional view showing a schematic configuration of a pressure sensor according to another modification; and

FIG. 9 is a side cross-sectional view showing a schematic configuration of a pressure sensor according to another modification.

### DETAILED DESCRIPTION

For example, in a type of pressure sensors, offset fluctuation in the sensor output occurs due to internal stress such as mounting stress and thermal stress. The offset fluctuation causes deterioration of detection accuracy. The present disclosure provides a device configuration that is as simple as possible and capable of appropriately suppressing deterioration of detection accuracy due to internal stress.

An example embodiment of the present disclosure provides a pressure sensor that generates an electrical output based on a fluid pressure. The pressure sensor includes a sensor chip and a support member. The sensor chip has a diaphragm and an inner space. The diaphragm has a thin plate shape and is bent in a thickness direction by the fluid pressure. The thickness direction defines a plate thickness of the thin plate shape. The inner space is provided by a space adjacent to the diaphragm in the thickness direction. The support member supports the sensor chip at a position separated from the diaphragm. A distance between a joint surface and a gauge surface is defined as h. The joint surface is one surface of the sensor chip, which is orthogonal to the thickness direction, and is joined to the support member. The gauge surface is another surface of the sensor chip, which is orthogonal to the thickness direction, and an opposite surface of the joint surface. When the sensor chip is viewed along the thickness direction, a diameter of an inscribed circle in case where an outer shape of the sensor chip is provided by a polygonal shape or a diameter in case where the outer shape of the sensor chip is provided by a circular shape is defined as d1. The plate thickness of the diaphragm is defined as t. When the diaphragm is viewed along the thickness direction, a diameter of an inscribed circle in case where an outer shape of the diaphragm is provided by a polygonal shape or a diameter in case where the outer shape of the diaphragm is provided by a circular shape is defined as d2.

h satisfies h=0.3 to 2.5 mm.

d1 satisfies d1=0.7 to 2.5 mm.

h/d1 satisfies h/d1≥1.

t satisfies t=5 to 15 μm.

d2 satisfies d2=350 to 700 μm.

An example embodiment of the present disclosure provides a pressure sensor that generates an electrical output based on a fluid pressure. The pressure sensor includes a sensor chip and a support member. The sensor chip has a diaphragm and a frame. The diaphragm has a thin plate shape and is bent in a thickness direction by the fluid pressure. The thickness direction defines a plate thickness of the thin plate shape. The frame is connected to an outer edge of the diaphragm to support the diaphragm. The support member supports the sensor chip at a position separated from the diaphragm. A distance between a joint surface and a gauge surface is defined as h. The joint surface is one surface of the sensor chip, which is orthogonal to the thickness direction, and is joined to the support member. The gauge surface is another surface of the sensor chip, which is orthogonal to the thickness direction, and an opposite surface of the joint surface. When the sensor chip is viewed along the thickness direction, a diameter of an inscribed circle in case where an outer shape of the sensor chip is provided by a polygonal shape or a diameter in case where the outer shape of the sensor chip is provided by a circular shape is defined as d1. The plate thickness of the diaphragm is defined as t. When the diaphragm is viewed along the thickness direction, a diameter of an inscribed circle in case where an outer shape of the diaphragm is provided by a polygonal shape or a diameter in case where the outer shape of the diaphragm is provided by a circular shape is defined as d2. When the frame is viewed along the thickness direction, a width of the frame is defined as f.

h satisfies h=0.3 to 2.5 mm.

d1 satisfies d1=0.7 to 2.5 mm.

t satisfies t=5 to 15 μm.

d2 satisfies d2=350 to 700 μm.

f satisfies f=(d1−d2)/2.

When an xy rectangular coordinate system, which is defined by x=h/d1 and y=f/d1, is set, coordinates (x, y) is within an area connecting the coordinates (1.43, 0.05), (1.43, 0.36), (1, 0.36), (0.68, 0.33), (0.56, 0.3), (1, 0.08), and (1.43, 0.05) in a described order.

Internal stress such as attaching stress may occur at the joint portion between the joint surface of the sensor chip and the support member. In an example embodiment of the present disclosure, offset fluctuation of the sensor output due to the transmission of the internal stress to the diaphragm can be suppressed as much as possible. Thus, the device configuration can be as simple as possible and appropriately suppress deterioration of detection accuracy due to internal stress.

Hereinafter, an embodiment will be described with reference to the drawings. In addition, in the following embodiments and modifications, the same reference numerals are given to the same or equivalent parts. In this case, in the following embodiments or modifications, the description in the preceding embodiment can be appropriately incorporated without technical contradiction or any special additional explanation.

### First Embodiment

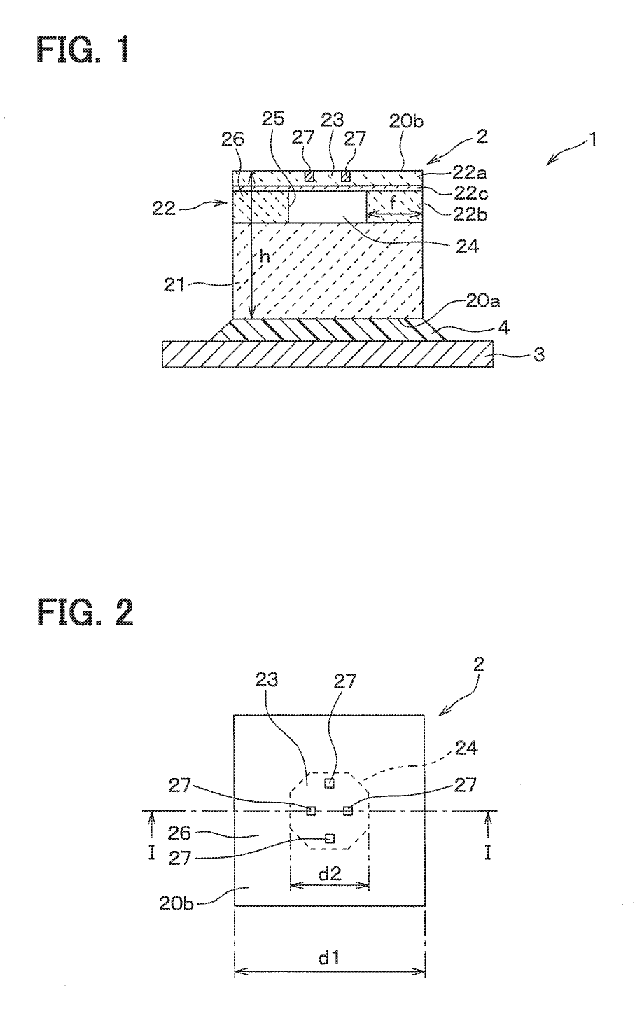

With reference to FIG. 1, a pressure sensor 1 of the present embodiment generates an electrical output based on a fluid pressure. Specifically, the pressure sensor 1 may outputs, as an absolute pressure of a fluid to be measured, a voltage corresponding to the pressure of the air sucked into the engine of the vehicle.

The pressure sensor 1 includes a sensor chip 2, a support member 3, and a joining layer 4. The support member 3 supports the sensor chip 2, and is provided by a metal lead frame, a ceramic substrate, a synthetic resin case, or the like. The support member 3 is arranged to face the sensor chip 2 with the joining layer 4 interposed therebetween. The joining layer 4 is made of a synthetic resin such as an epoxy resin. That is, the sensor chip 2 is joined to the support member 3 by the joining layer 4.

FIG. 1 corresponds to a cross-sectional view taken along line I-I of FIG. 2. Detailed configuration of the sensor chip 2 will be described with reference to FIG. 1 and FIG. 2. In FIG. 2, the illustration of the support member 3 and the joining layer 4 is omitted for simplicity of illustration. For the sake of simplicity of illustration and explanation, the details of the protection film, the conductive thin film for wiring, and the like which are normally provided in the sensor chip 2 are not shown and not described in each drawing. The same applies to the modifications after FIG. 5.

In the present embodiment, the sensor chip 2 has a rectangular parallelepiped shape. A joint surface 20a, which is one surface (that is, the bottom surface) of the sensor chip 2 and faces the support member 3, is joined to the support member 3 via the joining layer 4. A gauge surface 20b, which is the other surface (that is, the top surface) of the sensor chip 2, is provided opposite to the joint surface 20a so as to receive the fluid pressure.

The sensor chip 2 has a lower layer 21 and an upper layer 22. The lower layer 21 is disposed between the support member 3 and the upper layer 22. That is, the lower layer 21 has the above-described joint surface 20a. In the present embodiment, the lower layer 21 is provided by a silicon semiconductor layer having a (100) plane orientation. The upper layer 22 is joined to a surface of the lower layer 21 opposite to the joint surface 20a. That is, the upper layer 22 is disposed between the fluid which is the target of the absolute pressure measurement and the lower layer 21.

In the present embodiment, the upper layer 22 has a first semiconductor layer 22a, a second semiconductor layer 22b, and an intermediate oxide film 22c. The first semiconductor layer 22a is provided by a silicon semiconductor layer having a (110) plane orientation, and is separated from the lower layer 21. That is, the first semiconductor layer 22a has the above-described gauge surface 20b.

The second semiconductor layer 22b is provided by a silicon semiconductor layer having the (110) plane orientation, and is disposed between the lower layer 21 and the first semiconductor layer 22a. The intermediate oxide film 22c is provided by a silicon oxide film, and disposed between the first semiconductor layer 22a and the second semiconductor layer 22b. That is, the upper layer 22 is provided by an SOI layer having a stacked structure in which the first semiconductor layer 22a, the intermediate oxide film 22c, and the second semiconductor layer 22b are stacked and joined in the described order.

The sensor chip 2 has a diaphragm 23 and an internal space 24. The diaphragm 23 has a thin plate shape and is bent in the thickness direction by the fluid pressure. The “thickness direction” is the direction defining the plate thickness of the thin plate shape of the diaphragm 23, and is the direction orthogonal to the joint surface 20a and the gauge surface 20b. That is, the “thickness direction” corresponds to the vertical direction in FIG. 1. The “thickness direction” is also the direction defining the thickness of the sensor chip 2, that is, the distance between the joint surface 20a and the gauge surface 20b. Hereinafter, the vertical direction in FIG. 1 is simply referred to as the “thickness direction”.

In the sensor chip 2, the diaphragm 23 is arranged at a position apart from the support member 3. That is, the sensor chip 2 is supported by the support member 3 at a position apart from the diaphragm 23. Specifically, the diaphragm 23 receives the fluid pressure from the space outside the pressure sensor 1 on the gauge surface 20b.

As shown in FIG. 2, in the present embodiment, the diaphragm 23 is formed to have a regular octagonal shape viewed from the plan view, that is, viewed from the thickness direction. The internal space 24 is a space adjacent to the diaphragm 23 in the thickness direction. The internal space 24 is provided closer to the second semiconductor layer 22b than the diaphragm 23. That is, the diaphragm 23 is mainly provided by a portion of the first semiconductor layer 22a facing the internal space 24.

In the present embodiment, the internal space 24 is formed as an airtight space provided inside the sensor chip 2. Specifically, a recess 25, which corresponds to the internal space 24, is formed in the second semiconductor layer 22b. The recess 25 is provided in the second semiconductor layer 22b so as to open at least to the lower layer 21. As an example, the recess 25 may be formed to penetrate the second semiconductor layer 22b in the thickness direction. In this case, the diaphragm 23 is formed in the first semiconductor layer 22a and the intermediate oxide film 22c by a portion facing the internal space 24. That is, in this case, the thickness of the diaphragm 23 corresponds to the sum of the thickness of the first semiconductor layer 22a and the thickness of the intermediate oxide film 22c.

In the present embodiment, by the lower layer 21 joined to the upper layer 22, the inner space 24 is formed as the airtight space with the recess 25 closed by the lower layer 21. In the sensor chip 2, the diaphragm 23 is bent and deformed based on the difference between the internal pressure of the internal space 24 constituting the reference pressure chamber and the pressure of the space outside the diaphragm 23. In the second semiconductor layer 22b, a frame 26, which is a portion around the inner space 24, is connected to the outer surface of the diaphragm 23 so as to support the diaphragm 23.

The diaphragm 23 is provided with a plurality of gauge resistor 27. The gauge resistor 27 is provided by a piezoresistance element in which a resistance change occurs based on distortion. The gauge resistor 27 is formed by performing impurity diffusion on the first semiconductor layer 22a. As shown in FIG. 2, in the present embodiment, four gauge resistors 27 are formed on the diaphragm 23. The four gauge resistors 27 are electrically connected to each other so as to form a well-known Wheatstone bridge circuit.

One of the four gauge resistors 27, that is, the uppermost gauge resistor 27 in FIG. 2, is arranged in the vicinity of one of the sides of the regular octagonal outline in the plan view of the diaphragm 23, that is, the upper side of the dashed regular octagon in FIG. 2. Another one of the four gauge resistors 27, that is, the lowermost gauge resistor 27 in FIG. 2, is arranged in the vicinity of another one of the sides of the regular octagonal outline in the plan view of the diaphragm 23, that is, the lower side of the dashed regular octagon in FIG. 2. These two gauge resistors 27 are arranged in the vicinity of the outer surface of the diaphragm 23, and arranged symmetrically with respect to the center in the plan view of the diaphragm 23.

Another one of the four gauge resistors 27, that is, the leftmost gauge resistor 27 in FIG. 2, is arranged on another one of the sides of the regular octagonal outline in the plan view of the diaphragm 23, that is, on a substantially intermediate position between the left side of the dashed regular octagon in FIG. 2 and the center in the plan view of the diaphragm 23. Another one of the four gauge resistors 27, that is, the rightmost gauge resistor 27 in FIG. 2, is arranged on another one of the sides of the regular octagonal outline in the plan view of the diaphragm 23, that is, on a substantially intermediate position between the right side of the dashed regular octagon in FIG. 2 and the center in the plan view of the diaphragm 23. These two gauge resistors 27 are arranged symmetrically with respect to the center in the plan view of the diaphragm 23 at a position close to the center in the plan view of the diaphragm 23.

The sensor chip 2 of the present embodiment satisfies the following numerical expressions. In the following numerical expressions, the thickness of the sensor chip 2 is represented by h. The distance between the opposite sides of the sensor chip 2 in the plan view is represented by d1, and d1 corresponds to the inscribed circle diameter of the sensor chip 2. The thickness of the diaphragm 23 is represented by t. The short side length of the rectangular diaphragm 23 in the plan view is represented by d2, and d2 corresponds to the inscribed circle diameter of the rectangular diaphragm 23.

h=0.3 to 2.5 mm

d1=0.7 to 2.5 mm

h/d1≥1

t=5 to 15 μm

d2=350 to 700 μm

### Manufacturing Method of First Embodiment

The sensor chip 2 having the structure described above can be manufactured as follows. As described above, details of the protective film, the conductive thin film for wiring, and the like which are normally provided in the sensor chip 2 are omitted.

First, the SOI substrate which is a stacked body of the first semiconductor layer 22a, the intermediate oxide film 22c, and the second semiconductor layer 22b is prepared. Next, a gauge resistor 27 is formed on this SOI substrate. Further, the diaphragm 23 is formed in the SOI substrate by forming the recess 25 from the second semiconductor layer 22b.

In the forming of the recess 25, that is, the diaphragm 23, the anisotropic dry etching may be employed. The reasons are described as follows. Regarding the anisotropic dry etching, the etching rate of the intermediate oxide film 22c, which is provided by a silicon oxide film, is lower than the etching rate of the second semiconductor layer 22b, which is provided by the silicon semiconductor layer. Thus, the intermediate oxide film 22c functions as an etch stop layer, so that the diaphragm 23 is formed with good processing accuracy. Specifically, the thickness of the diaphragm 23 can be set with good accuracy.

The upper layer 22 is formed as described above. Thereafter, the lower layer 21 is joined to the upper layer 22 so as that the lower layer 21 makes the recess 25 airtight. Thereby, the sensor chip 2 having the airtight internal space 24 is formed.

### Effect of First Embodiment

Internal stress such as attaching stress may occur at the joint portion between the joint surface 20a of the sensor chip 2 and the support member 3. In the present embodiment, the sensor chip 2 satisfies h=0.3 to 2.5 mm, d1=0.7 to 2.5 mm, h/d1≥1, t=5 to 15 μm, d2=350 to 700 μm.

In such a configuration, the transmission of the internal stress generated at the above-described joint portion to the diaphragm 23 can be appropriately relieved by the lower layer 21. According to such a configuration, offset fluctuation of the sensor output due to the transmission of the internal stress to the diaphragm 23 can be suppressed as much as possible. Thus, with the present embodiment, the device can be as simple as possible, and the device makes it possible to appropriately suppress the deterioration of the detection precision due to the internal stress. Specifically, the influence of internal stress can be appropriately reduced without complicating the structure of the sensor chip 2 or increasing in size of the sensor chip 2.

In the present embodiment, the sensor chip 2 is mainly formed by the silicon semiconductor layer having the (110) plane orientation. Further, the diaphragm 23 has a regular octagonal shape in the plan view. Further, the two gauge resistors 27 are arranged in the vicinity of the center of the diaphragm 23 and the other two gauge resistors 27 are arranged in the vicinity of the outer surface of the diaphragm 23. With this configuration, the offset fluctuation of the sensor output can be more appropriately suppressed.

When h≥1 mm is satisfied in case of/d1≤1 mm, h/d1≥1 is satisfied. Thus, the sensor chip 2 can be formed, for example, by joining the lower layer 21 provided by a standard silicon wafer having a thickness of about 0.7 mm to the upper layer 22 in which the thickness is adjusted to 0.3 mm by polishing. Specifically, the lower layer 21 is formed using a silicon wafer having a wafer diameter of 200 mm and a thickness of 725±20 μm manufactured according to the SEMI standard, for example, SEMI stands for Semiconductor Equipment and Materials International. Thus, with this specific example, it is possible to achieve the device configuration that can appropriately suppress deterioration in detection accuracy due to internal stress without requiring a special processing such as wafer thickness adjustment to satisfy the condition of h/d1≥1.

### Simulation Result on First Embodiment

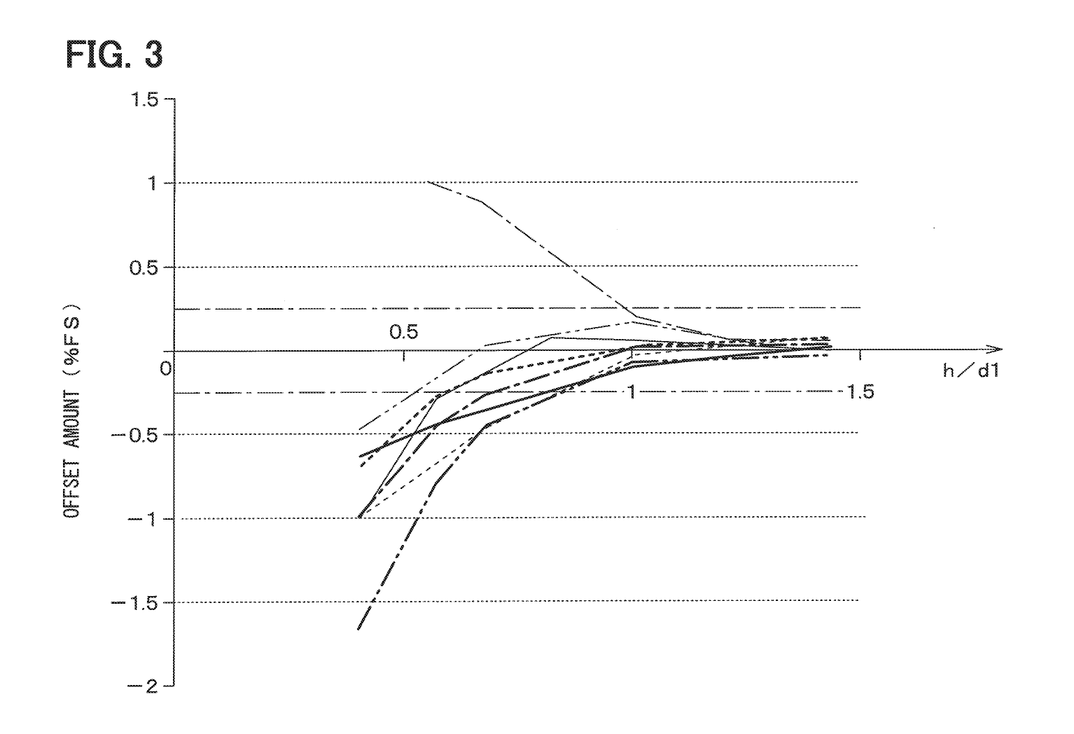

FIG. 3 shows a simulation result of the offset fluctuation of the sensor output when h/d1, t, d2 are varied on the premise of the configuration of the sensor chip 2 shown in FIG. 1 and FIG. 2. In this simulation, the plane shape of the sensor chip 2 is provided by a square shape.

The “offset amount (% FS)” on the vertical axis in FIG. 3 is calculated by the following numerical expression. In the following numerical expression, the rated output voltage as is defined by the output voltage when the rated pressure is applied to the diaphragm 23. The offset voltage an is defined by the output voltage when stress is applied to the joint surface 20a of the sensor chip 2 in a state where no pressure is applied to the diaphragm 23. The rated output voltage an and the offset voltage as are the results calculated by simulation.

offset amount(unit: % FS)=100×(σn/σs)

In FIG. 3, a thin dash-dot line shows a simulation result when d1=0.7 mm, d2=500 μm, t=9 μm and h is changed from 0.3 mm to 1.2 mm. A bold solid line shows a simulation result when d1=1.8 mm, d2=500 μm, t=9 μm, and h is changed from 0.7 mm to 2.5 mm. The bold dash-dot line shows a simulation result when h=1 mm, d2=500 μm, t=9 μm, and d1 is changed from 0.7 mm to 2.5 mm. A thin solid line shows a simulation result when h=1 mm, d2=630 μm, t=15 μm, and d1 is changed from 0.7 mm to 2.5 mm.

In FIG. 3, a bold dashed line shows a simulation result when h=1 mm, d2=500 μm, t=5 μm, and d1 is changed from 0.7 mm to 2.5 mm. The bold two-dot chain line shows a simulation result when h=1 mm, d2=500 μm, t=15 μm, and d1 is changed from 0.7 mm to 2.5 mm. A thin dashed line shows a simulation result when h=1 mm, d2=350 μm, t=9 μm, and d1 is changed from 0.7 mm to 2.5 mm. The thin two-dot chain line shows a simulation result when h=1 mm, d2=700 μm, t=9 μm, and d1 is changed from 0.7 mm to 2.5 mm.

In FIG. 3, the horizontal line of the dash-dot line indicates the offset amount of 0.25% FS and −0.25% FS. As is apparent from the simulation results of FIG. 3, the offset amount converges toward zero with the value of h/d1 increased. In particular, under the condition of h=0.3 to 2.5 mm, d1=0.7 to 2.5 mm, t=5 to 15 μm, d2=350 to 700 μm, by setting h/d1≥1, the offset amount falls within the range of ±0.25% FS. As a result, the improved sensor characteristics can be obtained.

### Second Embodiment

The sensor chip 2 of the present embodiment further satisfies the following numerical expressions on the premise of the configuration shown in FIG. 1 and FIG. 2. In the following numerical expressions, the width of the frame 26 in the plan view is represented by f.

h=0.3 to 2.5 mm

d1=0.7 to 2.5 mm

t=5 to 15 μm

d2=350 to 700 μm

f=(d1−d2)/2

The sensor chip 2 of the present embodiment satisfies the following condition.

“When the xy rectangular coordinate system, which is defined by x=h/d1 and y=f/d1, is considered, the coordinates (x, y) is within the area connecting the coordinates (1.43, 0.05), (1.43, 0.36), (1, 0.36), (0.68, 0.33), (0.56, 0.3), (1, 0.08), and (1.43, 0.05) in the described order.”

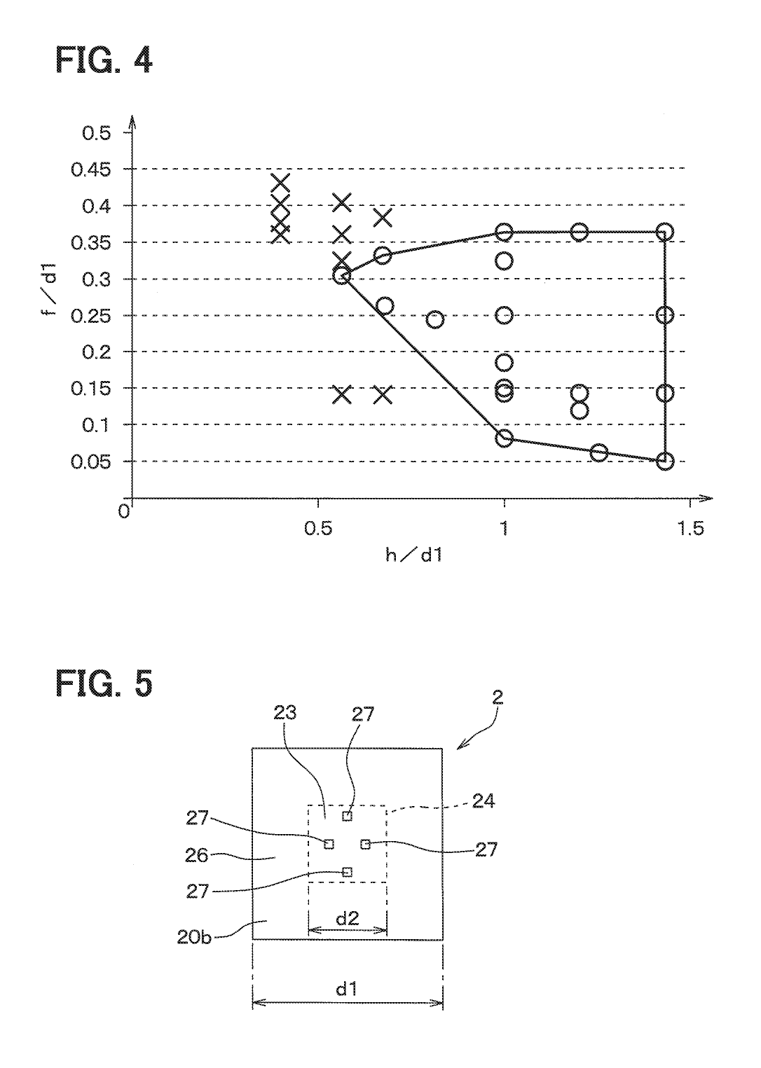

FIG. 4 shows simulation results of the offset fluctuation of the sensor output when h/d1, t, d2, f are varied on the premise of the configuration of the sensor chip 2 shown in FIG. 1 and FIG. 2. In this simulation, the plane shape of the sensor chip 2 is provided by a square shape.

The cross marks among the multiple plots in FIG. 4, indicate the examples where the offset amount does not fall within the range of ±0.25% FS. On the other hand, the circle marks indicate the examples where the offset amount falls within the range of ±0.25% FS. When the xy rectangular coordinate system, which is defined by x=h/d1 and y=f/d1, is considered, the polygon drawn in the figure indicates a boundary line of the area connecting the coordinates (1.43, 0.05), (1.43, 0.36), (1, 0.36), (0.68, 0.33), (0.56, 0.3), (1, 0.08), and (1.43, 0.05) in the described order.

As is apparent from the simulation results of FIG. 4, the offset amount falls within the range of ±0.25% FS by setting the values in order that the coordinates is in the above-described area including the boundary under the condition of h=0.3 to 2.5 mm, d1=0.7 to 2.5 mm, t=5 to 15 μm, and d2=350 to 700 μm. As a result, the improved sensor characteristics can be obtained.

(Modification)

The present disclosure is not limited to the embodiment described above and may be appropriately modified. Representative modifications will be described below. In the following description of variation examples, only the features different from those of the embodiments described above will be explained. Therefore, descriptions of previous embodiments can be referred to as required with respect to constituent elements given the same reference numerals as those of the embodiments described above in the following description of variation examples, unless there are technical contradictions or otherwise additionally described.

In the above-described embodiment, the concept of the vertical direction such as “bottom surface”, “top surface”, “lower layer 21”, “upper layer 22” and the like are merely set for convenience of explanation. That is, the attitude of the pressure sensor 1 in FIG. 1 is merely set for convenience so that the gauge surface 20b faces upward for simplicity of explanation. Thus, for example, depending on the usage of the pressure sensor 1, the gauge surface 20b may be the “bottom surface” or the “side surface” of the pressure sensor 1.

The outer shape of the sensor chip 2 in the plan view is not limited to a rectangular shape. When the outer shape of the sensor chip 2 in the plan view is provided by rectangular shape, the short side length corresponds to d1. When the outer shape of the sensor chip 2 in the plan view is provided by a polygonal shape other than the rectangle shape, the inscribed circle diameter corresponds to d1. When the outer shape of the sensor chip 2 in the plan view is provided by a circular shape, the diameter corresponds to d1.

The composition of the semiconductor constituting the lower layer 21 and the upper layer 22 is also not particularly limited. The lower layer 21 may be provided by a silicon semiconductor substrate or a glass substrate.

In the above-described embodiment, the thickness of the diaphragm 23 corresponds to the sum of the thickness of the first semiconductor layer 22a and the thickness of the intermediate oxide film 22c. The present disclosure is not limited to this specific example. That is, for example, it is possible to form the recess 25 so as not to penetrate the second semiconductor layer 22b in the thickness direction. In this case, the thickness of the remaining portion of the second semiconductor layer 22b where the recess 25 is formed is added to the thickness of the diaphragm 23.

The plane shape of the diaphragm 23 can also be appropriately changed. Specifically, for example, as shown in FIG. 5, the diaphragm 23 can be provided by a quadrangular shape, more preferably a rectangular shape in the plan view. In this case, in the plan view, the frame 26 is provided by a tubular shape having a quadrangular shape, which corresponds to the rectangular diaphragm 23.

That is, for example, the sensor chip 2 is mainly provided by a silicon semiconductor layer having the (110) plane orientation, and the diaphragm 23 can be provided by a quadrangular shape in the plan view. In this case, d2 corresponds to the inscribed circle diameter in the rectangular shape or the short side length in the rectangular shape. In this case, the diaphragm 23 can be formed at low cost and with high accuracy using alkali anisotropic etching.

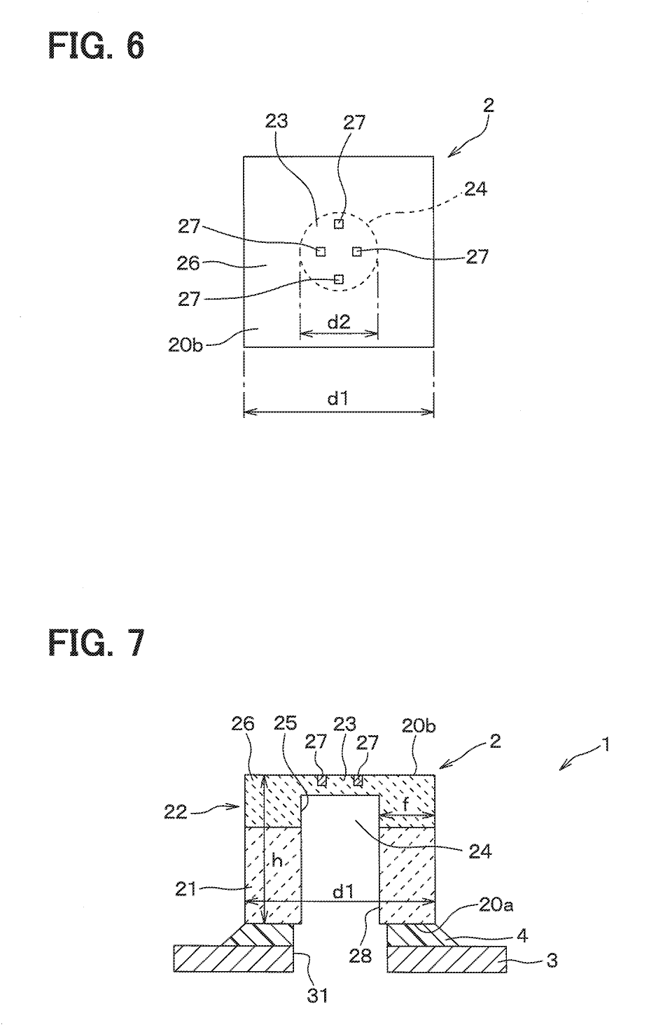

Alternatively, for example, as shown in FIG. 6, the diaphragm 23 can be provided by a circular shape in the plan view. When the plane shape of the diaphragm 23 is provided by the circular shape as shown in FIG. 6, d2 corresponds to the diameter in the circular shape. When the plane shape of the diaphragm 23 is provided by the circular shape shown in FIG. 6 or the regular octagonal shape shown in FIG. 2, the influence of the sensor output due to internal stress can be further reduced compared with the case where the plane shape of the diaphragm 23 is provided by the quadrangular shape shown in FIG. 5.

The internal space 24 is not limited to the airtight space. As shown in FIG. 7, a communication hole 28 penetrating the lower layer 21 in the thickness direction may be formed at a position corresponding to the recess 25 of the upper layer 22. An opening hole 31 penetrating the support member 3 in the thickness direction may be formed at a position corresponding to the communication hole 28. The internal space 24 may be formed to include a space inside the recess 25 and a space inside the communication hole 28 provided in the lower layer 21. Further, the internal space 24 may communicate with the outside via the opening hole 31 provided in the support member 3.

The pressure sensor 1 having such a configuration outputs a voltage corresponding to the pressure difference on both sides of the diaphragm 23, that is, on the upper side and the lower side of the diaphragm 23 in FIG. 7. That is, the present disclosure can be applied not only to the absolute pressure sensor described in the above-described embodiment, but also to a differential pressure sensor as shown in FIG. 7. Specifically, the pressure sensor 1 can be used as a so-called exhaust gas differential pressure sensor that detects a differential pressure between, for example, an upstream exhaust pressure and a downstream exhaust pressure of a DPF (diesel particulate filter).

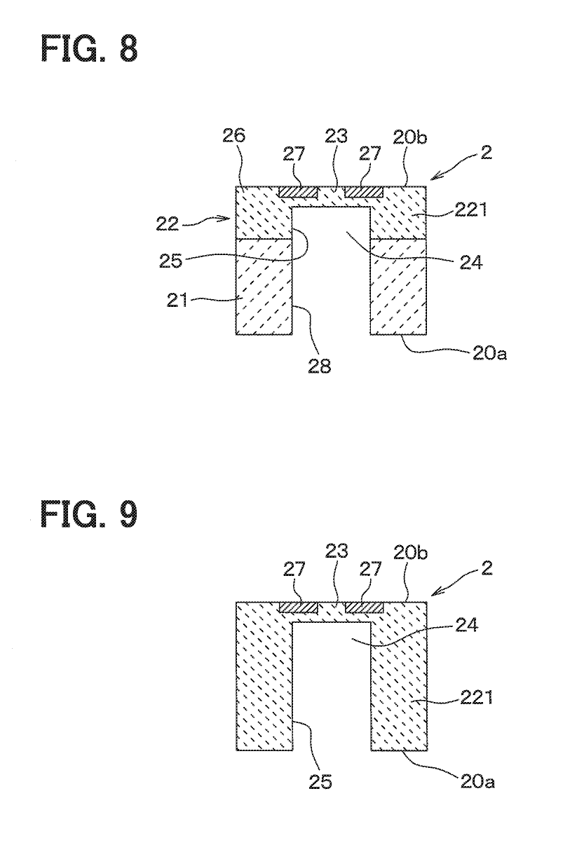

The configuration of the upper layer 22 is not limited to the SOI layer as described in the above-described embodiment. Specifically, as shown in FIG. 8, the upper layer 22 may be provided by a semiconductor layer 221 having a diaphragm 23 and a recess 25 corresponding to the internal space 24. That is, the upper layer 22 in this modification may be formed by providing the recess 25 and the gauge resistance 27 with respect to the semiconductor layer 221. The semiconductor layer 221 may be provided as a seamless single layer semiconductor substrate. In this case, the semiconductor layer 221 may have the (110) plane orientation. The present modification is not limited to the differential pressure sensor shown in FIG. 8. That is, this modification may also be applied to an absolute pressure sensor as shown in FIG. 1.

The plane orientation in each semiconductor layer is also not particularly limited. For example, the plane orientation of the first semiconductor layer 22a is not limited to (110). The second semiconductor layer 22b may have the (110) plane orientation, the (100) plane orientation, or the (111) plane orientation. Similarly to the first semiconductor layer 22a and the second semiconductor layer 22b, the lower layer 21 may have the (110) plane orientation or the (111) plane orientation. Specifically, for example, each of the lower layer 21 the first semiconductor layer 22a, and the second semiconductor layer 22b may have the (110) plane orientation. In any of these cases, the effect of reducing the internal stress can be provided.

In each of the above-described examples, the sensor chip 2 has the stacked structure of the lower layer 21 and the upper layer 22. The present disclosure is not limited to this specific example. That is, as shown in FIG. 9, the sensor chip 2 may be formed by arranging the recess 25 and the gauge resistance 27 to the semiconductor layer 221. The semiconductor layer 221 may be formed as a seamless single layer semiconductor substrate. In this case, the semiconductor layer 221 may have the (110) plane orientation. The present modification is not limited to the differential pressure sensor shown in FIG. 9. That is, this modification may also be applied to the absolute pressure sensor as shown in FIG. 1.

The number, arrangement, and electrical connection configuration of the gauge resistors 27 are also not limited to the above-described example.

The present disclosure is not limited to pressure sensor 1 of gauge resistance type (i.e., piezoelectric type) as described in the example above. That is, the present disclosure may also be applicable to a pressure sensor of a type different from the gauge resistance type. Further, the pressure sensor 1 is not limited to a vehicle sensor.

The fluid of which the pressure is to be measured is not limited to gas such as intake air, exhaust gas and the like. That is, liquids, gels, supercritical fluids, or the like may also be a target to be measured. Further, the fluid at the time of pressure measurement may be in a fluid state, in a stationary state, or in a state equivalent thereto. That is, the measured pressure may be a static pressure. In this specification, the term “measurement” refers to generating an electrical output based on the fluid pressure. The electrical output may include a digital signal or digital data other than the analog signal (for example, the voltage or the like). “Measurement” may also be paraphrased as “detection”.

Variation examples are not limited to the examples illustrated above. Namely, various variation examples can be combined with each other. Also, various embodiments can be combined with each other. Moreover, all or some of the variation examples described above can be combined with combinations of various embodiments as required.

1. A pressure sensor configured to generate an electrical output based on a fluid pressure,
the pressure sensor comprising:
a sensor chip having a diaphragm and an inner space, the diaphragm having a thin plate shape and configured to be bent in a thickness direction by the fluid pressure, the thickness direction defining a plate thickness of the thin plate shape, and the inner space provided by a space adjacent to the diaphragm in the thickness direction; and
a support member configured to support the sensor chip at a position separated from the diaphragm,
wherein:
a distance between a joint surface and a gauge surface is defined as h;
the joint surface is one surface of the sensor chip, which is orthogonal to the thickness direction, and is joined to the support member;
the gauge surface is another surface of the sensor chip, which is orthogonal to the thickness direction, and an opposite surface of the joint surface;
when the sensor chip is viewed along the thickness direction, a diameter of an inscribed circle in case where an outer shape of the sensor chip is provided by a polygonal shape or a diameter in case where the outer shape of the sensor chip is provided by a circular shape is defined as d1;
the plate thickness of the diaphragm is defined as t;
when the diaphragm is viewed along the thickness direction, a diameter of an inscribed circle in case where an outer shape of the diaphragm is provided by a polygonal shape or a diameter in case where the outer shape of the diaphragm is provided by a circular shape is defined as d2;
h satisfies h=0.3 to 2.5 mm;
d1 satisfies d1=0.7 to 2.5 mm;
h/d1 satisfies h/d1≥1;
t satisfies t=5 to 15 μm; and
d2 satisfies d2=350 to 700 μm.

2. The pressure sensor according to claim 1, wherein
d1 satisfies d1≤1 mm.

3. The pressure sensor according to claim 1, wherein
when the diaphragm is viewed along the thickness direction, the outer shape of the diaphragm is provided by the circular shape, a square shape, or an octagonal shape.

4. The pressure sensor according to claim 1, wherein
the sensor chip includes:
an upper layer having a stacked structure of a first semiconductor layer, a second semiconductor layer, and an intermediate oxide film, the first semiconductor layer being provided by a silicon semiconductor layer having a (110) plane orientation, the first semiconductor layer forming the diaphragm, the second semiconductor layer being provided by the silicon semiconductor layer, the second semiconductor layer forming a recess corresponding to the inner space, the intermediate oxide film being arranged between the first semiconductor layer and the second semiconductor layer; and the intermediate oxide film being provided by a silicon oxide film; and
a lower layer being joined to the upper layer, and provided by the silicon semiconductor layer.

5. The pressure sensor according to claim 1, wherein
the sensor chip includes:
an upper layer having the diaphragm and a recess corresponding to the inner space, and being provided by a silicon semiconductor layer having a (110) plane orientation; and
a lower layer being provided by the silicon semiconductor layer, and joined to the upper layer.

6. A pressure sensor configured to generate an electrical output based on a fluid pressure,
the pressure sensor comprising:
a sensor chip having a diaphragm and a frame, the diaphragm having a thin plate shape and configured to be bent in a thickness direction by the fluid pressure, the thickness direction defining a plate thickness of the thin plate shape, and the frame connected to an outer surface of the diaphragm to support the diaphragm; and
a support member configured to support the sensor chip at a position separated from the diaphragm,
wherein:
a distance between a joint surface and a gauge surface is defined as h;
the joint surface is one surface of the sensor chip, which is orthogonal to the thickness direction, and is joined to the support member;
the gauge surface is another surface of the sensor chip, which is orthogonal to the thickness direction, and an opposite surface of the joint surface;
when the sensor chip is viewed along the thickness direction, a diameter of an inscribed circle in case where an outer shape of the sensor chip is provided by a polygonal shape or a diameter in case where the outer shape of the sensor chip is provided by a circular shape is defined as d1;
the plate thickness of the diaphragm is defined as t;
when the diaphragm is viewed along the thickness direction, a diameter of an inscribed circle in case where an outer shape of the diaphragm is provided by a polygonal shape or a diameter in case where the outer shape of the diaphragm is provided by a circular shape is defined as d2;
when the frame is viewed along the thickness direction, a width of the frame is defined as f;
h satisfies h=0.3 to 2.5 mm;
d1 satisfies d1=0.7 to 2.5 mm;
t satisfies t=5 to 15 μm;
d2 satisfies d2=350 to 700 μm;
f satisfies f=(d1−d2)/2; and
when an xy rectangular coordinate system, which is defined by x=h/d1 and y=f/d1 is set, coordinates (x, y) is within an area connecting coordinates (1.43, 0.05), (1.43, 0.36), (1, 0.36), (0.68, 0.33), (0.56, 0.3), (1, 0.08), and (1.43, 0.05) in a described order.

7. The pressure sensor according to claim 6, wherein
d1 satisfies d1≤1 mm.

8. The pressure sensor according to claim 6, wherein
when the diaphragm is viewed along the thickness direction, the outer shape of the diaphragm is provided by the circular shape, a square shape, or an octagonal shape.

9. The pressure sensor according to claim 6, wherein
the sensor chip includes:
an upper layer having a stacked structure of a first semiconductor layer, a second semiconductor layer, and an intermediate oxide film, the first semiconductor layer being provided by a silicon semiconductor layer having a (110) plane orientation, the first semiconductor layer forming the diaphragm, the second semiconductor layer being provided by the silicon semiconductor layer, the second semiconductor layer forming a recess corresponding to the inner space, the intermediate oxide film being arranged between the first semiconductor layer and the second semiconductor layer, and the intermediate oxide film being provided by a silicon oxide film; and
a lower layer being joined to the upper layer, and provided by the silicon semiconductor layer.

10. The pressure sensor according to claim 6, wherein
the sensor chip includes:
an upper layer having the diaphragm and a recess corresponding to the inner space, and being provided by a silicon semiconductor layer having a (110) plane orientation; and
a lower layer being provided by the silicon semiconductor layer, and joined to the upper layer.
